(19) United States
(12) Patent Application Publication
(10) Pub. No.: US 2025/0227940 A1
(43) Pub. Date: Jul. 10, 2025

(54) METHOD FOR PRODUCING A TRENCH CAPACITOR STRUCTURE AND TRENCH CAPACITOR

(71) Applicant: Fraunhofer-Gesellschaft zur Förderung der angewandten Forschung e.V., München (DE)

(72) Inventors: Tom BECKER, Erlangen (DE); Tobias ERLBACHER, Poxdorf (DE)

(21) Appl. No.: 19/014,846

(22) Filed: Jan. 9, 2025

(30) Foreign Application Priority Data
Jan. 10, 2024 (DE) 10 2024 200 211.9

(51) Int. Cl. H10D 1/00; H10D 1/68

(52) U.S. Cl. CPC H10D 1/042; H10D 1/716

(57) ABSTRACT

Method for producing a trench capacitor structure, including the steps of providing a silicon substrate with a trench structure comprising a plurality of recesses in a main surface of the silicon substrate; forming a first silicon dioxide layer at least in the recesses of the silicon substrate; depositing a first silicon nitride layer on the first silicon dioxide layer; depositing a second silicon dioxide layer on the first silicon nitride layer by depositing a polycrystalline silicon layer and oxidizing the polycrystalline silicon layer; and depositing a second silicon nitride layer on the second silicon dioxide layer.

### CROSS-REFERENCE TO RELATED APPLICATIONS

This application claims priority from German Patent Application No. 10 2024 200 211.9, which was filed on Jan. 10, 2024, and is incorporated herein in its entirety by reference.

Embodiments according to the invention relate to a method for producing a trench capacitor structure and to a trench capacitor, or to a method for producing a dielectric layer stack and to a trench capacitor having a dielectric layer stack. The dielectric layer stack is a dielectric (ON)x stack with x≥2, for example for Si-RC snubber devices, wherein a silicon dioxide layer is denoted by O and a silicon nitride layer is denoted by N.

### BACKGROUND OF THE INVENTION

Different concepts for reducing substrate bending when producing an integrated capacitor are known.

The patent DE102019204503B3 discloses, for example, the introduction of a stress-free nitride layer to increase the peak voltage strength to 1200 V and to reduce the disk bending. However, a further increase in the voltage strength is hardly possible with such a design, without losing integration density (e.g.: by thicker dielectric layers) or to drastically increase the wafer bending (e.g.: thicker dielectric layers with simultaneous increase of the surface by deeper hole structuring).

In view of this, there is a need for a concept for devices having dielectric, e.g., trench capacitors or RC snubbers, or for dielectric layer structures for increasing a breakdown voltage with constant or increased integration density (capacitance) taking into account the disk bending by thermomechanical stress during/after the deposition of the dielectric layers.

### SUMMARY

According to an embodiment, a method for producing a trench capacitor structure may have the steps of: providing a silicon substrate with a trench structure including a plurality of recesses in a main surface of the silicon substrate; forming a first silicon dioxide layer at least in the recesses of the silicon substrate; depositing a first silicon nitride layer on the first silicon dioxide layer; depositing a second silicon dioxide layer on the first silicon nitride layer by depositing a polycrystalline silicon layer and oxidizing the polycrystalline silicon layer; and depositing a second silicon nitride layer on the second silicon dioxide layer.

According to another embodiment, a trench capacitor may have: a dielectric layer structure including a first silicon dioxide layer, a first silicon nitride layer, a second silicon dioxide layer and a second silicon nitride layer; wherein the first silicon dioxide layer, the first silicon nitride layer, the second silicon dioxide layer and the second silicon nitride layer are adjacent to one another in this order.

According to one aspect of the present invention, the inventors have recognized that a problem in the production of a trench capacitor structure is that a voltage strength can hardly be increased without losing the integration density or drastically increasing the bending of the silicon substrate. According to one aspect of the present invention, this difficulty is overcome by providing, in a trench structure of a silicon substrate, a dielectric layer stack of at least two silicon dioxide layers and at least two silicon nitride layers, wherein the silicon dioxide layers and the silicon nitride layers are disposed alternately one above the other. Although a higher capacitance density can be achieved with trench capacitors compared to planar capacitors, at the same time it has to be considered that manufacturing mechanisms for planar capacitors cannot be simply applied to trench capacitors, in particular since the coating of trench structures has to withstand different challenges, e.g., in connection with uniform layer thicknesses and substrate bending, than a coating of planar surfaces. In this context, the inventors have recognized that, due to the alternating formation of silicon dioxide layers and silicon nitride layers in trench structures, not only can a substrate bending be controlled during the formation of the layer stack, but it is also made possible that a hole depth and thus the surface enlargement of the capacitor can be increased. In particular, it has been found that the layer stack formed in the trench structure has to comprise at least two silicon dioxide layers and at least two silicon nitride layers in order to keep the substrate bending as low as possible at large hole depths. Furthermore, it has been observed that, in the context of trench structures, a silicon dioxide layer can be formed particularly advantageously on a silicon nitride layer, i.e. with high quality, such as, e.g., with uniform structure, with uniform layer thickness and/or in a low-defect manner, when a polycrystalline silicon layer is deposited and the same is oxidized. Thus, trench capacitor structures having a dielectric layer stack with high breakdown strength can be obtained.

Accordingly, an embodiment relates to a method for producing a trench capacitor structure. The method comprises providing a silicon substrate with a trench structure comprising a plurality of recesses in a main surface of the silicon substrate. Furthermore, the method comprises forming a first silicon dioxide layer in the recesses of the silicon substrate; depositing a first silicon nitride layer on the first silicon dioxide layer; depositing a second silicon dioxide layer on the first silicon nitride layer by depositing a polycrystalline silicon layer and oxidizing the polycrystalline silicon layer; and depositing a second silicon nitride layer on the second silicon dioxide layer. The first silicon dioxide layer is formed at least in the recesses of the silicon substrate. Optionally, the first silicon dioxide layer can additionally be formed on at least parts of the main surface of the silicon substrate or on the complete main surface of the silicon substrate. The first silicon dioxide layer is, for example, further formed on parts of the main surface of the silicon substrate that connect the recesses to one another. Thus, at least in the recesses of the silicon substrate and optionally additionally on the main surface of the silicon substrate, an (ON)x stack with x≥2 is formed, wherein a silicon dioxide layer is denoted by O and a silicon nitride layer is denoted by N. The index x indicates how many ON layer pairs are disposed on top of each other.

According to an embodiment, during oxidizing the polycrystalline silicon layer, an oxynitride layer is formed between the first silicon nitride layer and the second silicon dioxide layer. This leads to a clean interface between the silicon nitride layer and the silicon dioxide layer. Due to the fact that the oxynitride layer is formed, possible defects between the silicon nitride layer and the silicon dioxide layer are reduced and an electrical breakdown strength is increased.

According to an embodiment, during oxidizing the polycrystalline silicon layer, the polycrystalline silicon layer is completely converted into the second silicon dioxide layer. The inventors have found that even if only a thin polycrystalline silicon layer remains, unpredictable electrical processes can occur in the trench capacitor structure and only a low breakdown strength can be achieved. This is based on the finding that the polycrystalline silicon layer is a semiconductor layer. However, since the layer stack of alternating silicon dioxide and silicon nitride layers serves as dielectric in the trench capacitor structure, even a thin semiconductor layer between the layers with insulating material reduces a breakdown strength of the layer stack.

Optionally, after the polycrystalline silicon layer has been completely converted into the second silicon dioxide layer, oxidizing is continued in order to partially oxidize the first silicon nitride layer and to form an oxynitride layer between the first silicon nitride layer and the second silicon dioxide layer. As a result, a clean interface between the silicon nitride layer and the silicon dioxide layer and a high electrical breakdown strength are achieved. Oxidizing is continued, for example, for a period of at least 5 min, 20 min or 1 h. The period is, for example, in a range of 5 min-5 h, 20 min-5 h or 1 h-5 h, advantageously in a range of 5 min-1 h. In an embodiment, oxidizing is continued for approximately 20 min or for approximately 1 h.

According to an embodiment, the polycrystalline silicon layer is undoped. This is based on the finding that as a result, a silicon dioxide layer with high quality can be formed in the trench capacitor structure. The inventors have found, in particular, that as a result, a very pure silicon dioxide layer with low leakage current can be achieved. This improves the electrical properties of the trench capacitor structure.

According to an embodiment, the polycrystalline silicon layer is deposited on the first silicon nitride layer by means of low-pressure vapor deposition, i.e. using an LPCVD method. It has been recognized that although a deposition of a silicon oxide layer directly on the silicon nitride layer by means of LPCVD methods leads to a defect-rich interface and a low electrical breakdown strength, an LPCVD deposition of polycrystalline silicon and subsequent oxidation of the polycrystalline silicon leads to a clean interface and high electrical breakdown strength.

According to an embodiment, the first silicon dioxide layer, the first silicon nitride layer, the second silicon dioxide layer and/or the second silicon nitride layer are deposited with a respective layer thickness in a range from 100 nm to 1000 nm or 330 nm to 530 nm. The individual layers can have different layer thicknesses. It has further been found that a sequence of several thin silicon dioxide and silicon nitride layers achieves lower substrate bending and higher breakdown strength than a sequence of less thick silicon dioxide and silicon nitride layers.

According to an embodiment, the first silicon dioxide layer is formed in the recesses of the silicon substrate by means of thermal growth, the first silicon nitride layer is deposited on the first silicon dioxide layer by means of low-pressure vapor deposition, i.e. an LPCVD method, and the second silicon nitride layer is deposited on the second silicon dioxide layer by means of low-pressure vapor deposition, i.e. an LPCVD method.

According to an embodiment, a silicon nitride layer together with a silicon dioxide layer form a layer pair, wherein the silicon nitride layer is arranged on the silicon dioxide layer, e.g., viewed from the silicon substrate in the layer stacking direction. In other words, a silicon dioxide layer and a silicon nitride layer on the silicon dioxide layer can be referred to as a layer pair. A layer pair can also be referred to herein as a layer stack unit. The first silicon dioxide layer and the first silicon nitride layer form, e.g., a first layer pair and the second silicon dioxide layer and the second silicon nitride layer form, e.g., a second layer pair. At least one further layer pair including a silicon dioxide layer and a silicon nitride layer can be deposited on the second layer pair, i.e. viewed from the silicon substrate in the layer stacking direction. In this case, e.g., the silicon dioxide layer of the respective further layer pair is deposited on the silicon nitride layer of the respectively preceding layer pair. The deposition of layer pairs including a silicon dioxide layer and a silicon nitride layer is repeated several times. Thus, at least in the recesses of the silicon substrate and optionally additionally on the main surface of the silicon substrate, an (ON)x stack with x≥3 is formed, wherein a silicon dioxide layer is denoted by O and a silicon nitride layer is denoted by N. The at least one further layer pair is deposited, e.g., on the second layer pair such that a layer structure with alternating silicon dioxide and silicon nitride layers is formed. Starting from the second layer pair, the silicon dioxide layer of the respective layer pair is deposited by depositing a polycrystalline silicon layer and oxidizing the polycrystalline silicon layer. The inventors recognized that even with a thicker overall dielectric stack layer, i.e. with more silicon dioxide and silicon nitride layers alternately one above the other, the integration density can be obtained or even increased. It has been found that, due to the alternating layering of silicon dioxide and silicon nitride layers one above the other, a substrate bending can be kept low and at the same time a layer stack with a large overall thickness, e.g., of at least 1600 nm, 2000 nm or 3000 nm, can be realized in the recesses of the silicon substrate. As a result, a layer stack with high breakdown strength, e.g., of at least 1200 V, 1400 V or 1500 V, is achieved. It is particularly advantageous if, further, an oxynitride layer is respectively formed between the individual layer pairs.

According to an embodiment, the polycrystalline silicon layers described herein are oxidized by means of dry-chemical oxidation or wet-chemical oxidation. In other words, the silicon dioxide layers described herein are thermally grown. The dry-chemical or wet-chemical oxidation can also be referred to herein as dry-chemical or wet-chemical re-oxidation or up-oxidation. The wet-chemical oxidation can also be referred to herein as moist-chemical oxidation. The inventors recognized that the formation of silicon dioxide layers by means of dry-chemical or wet-chemical oxidation of polycrystalline silicon results in cleaner interfaces and also a higher breakdown strength than if the silicon dioxide layers are deposited directly by means of LPCVD methods (low-pressure chemical vapor deposition) or PECVD methods (plasma-enhanced chemical vapor deposition). As a result, silicon dioxide layers with high quality are generated and the electrical properties of the trench capacitor structure are improved. The wet-chemical oxidation has the advantage that the silicon dioxide layers can be formed more quickly than with the dry-chemical oxidation and the dry-chemical oxidation has the advantage over the wet-chemical oxidation that a higher breakdown strength of the layer stack formed in the recesses of the silicon substrate can be achieved.

According to an embodiment, an RC snubber element is formed or produced with the method described herein.

A further embodiment relates to a trench capacitor comprising a dielectric layer structure comprising a first silicon dioxide layer, a first silicon nitride layer, a second silicon dioxide layer and a second silicon nitride layer. The trench capacitor includes, e.g., a silicon substrate with a trench structure comprising a plurality of recesses in a main surface of the silicon substrate. The dielectric layer structure is arranged, e.g., in the recesses of the silicon substrate. The first silicon dioxide layer, the first silicon nitride layer, the second silicon dioxide layer and the second silicon nitride layer are arranged in this order. The layers can be directly adjacent to one another. Optionally, an oxynitride layer is arranged between the first silicon nitride layer and the second silicon dioxide layer, wherein the oxynitride layer can also be considered as part of the first silicon nitride layer. The second silicon dioxide layer can be an oxidized polycrystalline silicon layer.

The trench capacitor is based on the same considerations as the method described above. The trench capacitor can be supplemented with all features and functions that are also described with regard to the method. Further, at least parts of the trench capacitor can be produced with a method described herein.

### BRIEF DESCRIPTION OF THE DRAWINGS

Embodiments of the present invention will be detailed subsequently referring to the appended drawings, in which:

FIG. 1a a block diagram of an inventive embodiment of a method for producing a trench capacitor structure;

FIG. 1b schematic illustrations of method steps of an inventive embodiment of a method for producing a trench capacitor structure;

FIG. 2 schematic illustrations of method steps of an inventive embodiment of a method for producing a dielectric layer structure with oxynitride layer;

FIG. 3 a schematic illustration of an inventive embodiment of a trench capacitor structure with a plurality of ON layer pairs;

FIG. 4 a schematic illustration of an inventive embodiment of a trench capacitor structure with a plurality of ON layer pairs, which each further comprise an oxynitride layer;

FIG. 5 a diagram with a characteristic curve of an inventive embodiment of a snubber device, the silicon dioxide layers of which have been deposited by means of dry-chemical oxidation, and a characteristic curve of a snubber device, the silicon dioxide layers of which have been deposited by means of LPCVD deposition;

FIG. 6 a diagram with a characteristic curve of an inventive embodiment of a snubber device, the silicon dioxide layers of which have been deposited by means of dry-chemical oxidation, and a characteristic curve of an inventive embodiment of a snubber device, the silicon dioxide layers of which have been deposited by means of wet-chemical oxidation; and

FIG. 7 a diagram with a characteristic curve of an inventive embodiment of a snubber device, the silicon dioxide layers of which have been deposited by means of dry-chemical oxidation, and a characteristic curve of a snubber device with a stress-free nitride layer.

### DETAILED DESCRIPTION OF THE INVENTION

Before embodiments of the present invention are explained in more detail below with reference to the drawings, it is noted that identical, functionally identical or equal elements, objects and/or structures are provided with the same or similar reference numbers in the different figures, so that the description of these elements illustrated in different embodiments is interchangeable or interapplicable.

To facilitate the description of the various embodiments, some of the figures comprise a Cartesian coordinate system x, y, z, wherein the x-y-plane corresponds to a first main surface area of a substrate (=a reference plane=x-y-plane), i.e. is parallel to the same, wherein the direction perpendicular upwards with respect to the reference plane (x-y-plane) corresponds to the “+z” direction, and wherein the direction perpendicular downwards with respect to the reference plane (x-y-plane) corresponds to the “−−z” direction. In the following description, the term “lateral” means a direction parallel to the x- and/or y-direction, i.e. parallel to the x-y-plane, wherein the term “vertical” means a direction parallel to the z-direction.

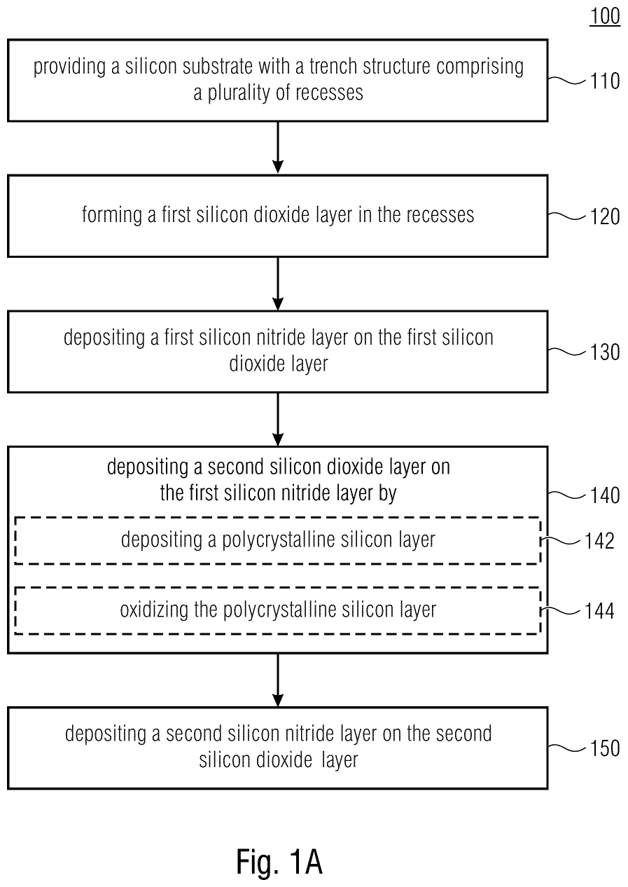

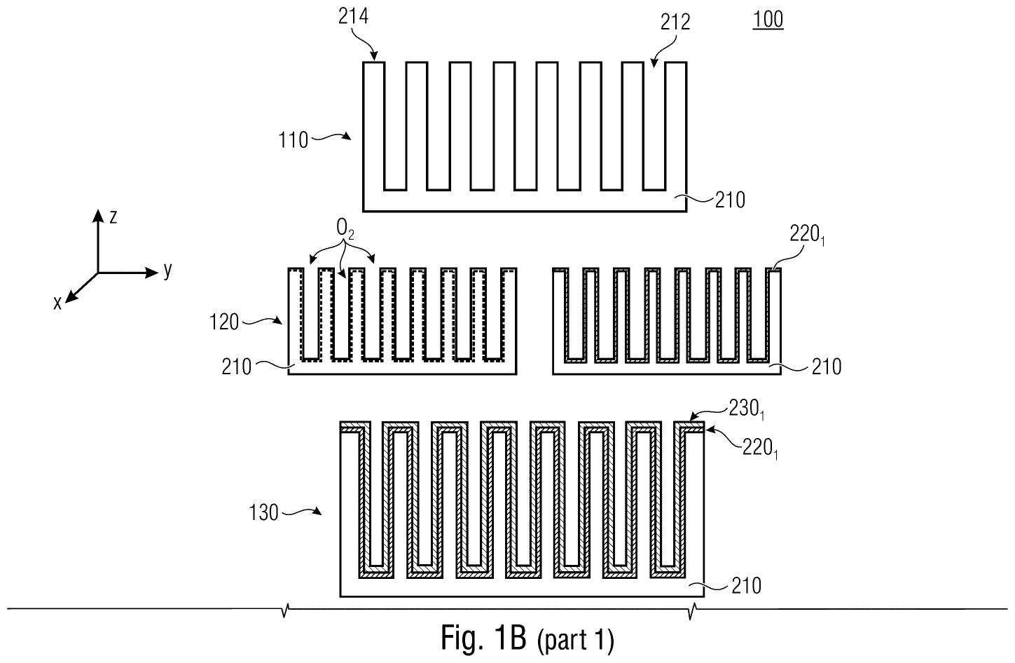

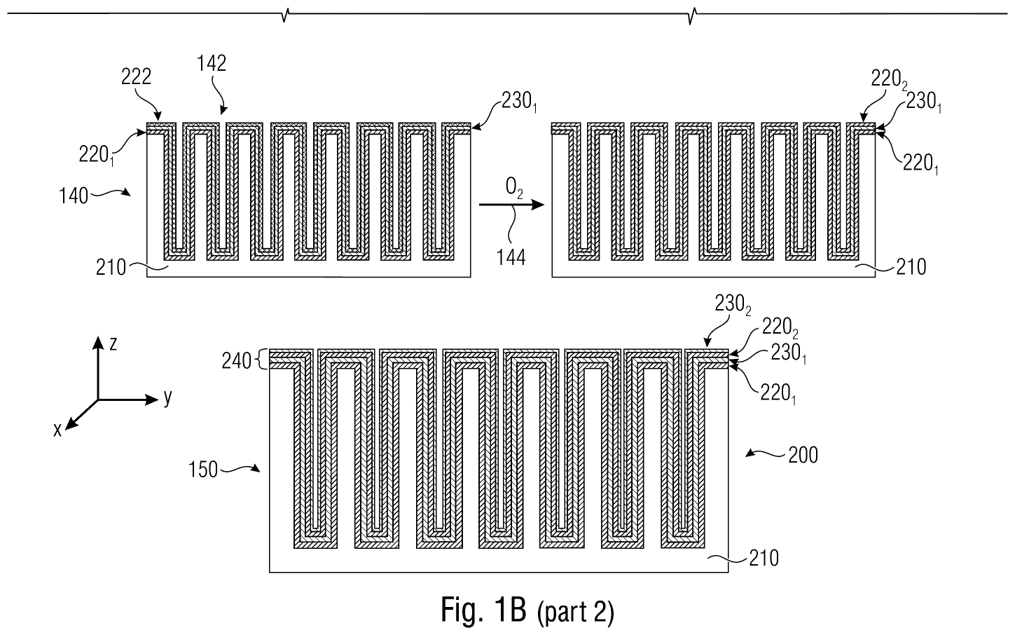

FIGS. 1a and 1b show a method 100 for producing a trench capacitor structure 200 or a trench capacitor.

The method 100 includes providing 110 a silicon substrate 210 with a trench structure. The trench structure comprises a plurality of recesses 212 in a main surface 214 of the silicon substrate 210. The silicon substrate 210 can be, for example, a silicon wafer. For the method 100, for example, a prefabricated silicon substrate 210 with an already integrated trench structure can be used. Alternatively, providing 110 the silicon substrate 210 with the trench structure can comprise forming the trench structure in the main surface 214 of the silicon substrate 210. The trench structure is formed, for example, by means of silicon substrate patterning. Forming the trench structure in the main surface 214 of the silicon substrate 210 can comprise one or more lithographic steps and one or more etching steps.

A further step of the method 100 relates to forming 120 a first silicon dioxide layer 2201 at least in the recesses 212 of the silicon substrate 210. In FIG. 1b, the first silicon dioxide layer 2201 is exemplarily also formed on the main surface 214 of the silicon substrate 210. The first silicon dioxide layer 2201 is exemplarily formed by means of thermal growth or thermal oxidation. For this purpose, e.g., the silicon substrate 210 is dry-chemically or wet-chemically oxidized, wherein dry-chemical oxidation is advantageous. For example, surfaces within the plurality of recesses 212 and optionally the main surface 214 or parts of the main surface 214 are oxidized in order to form the first silicon dioxide layer 2201. The first silicon dioxide layer 2201 comprises, e.g., SiO2 material or thermal oxide. A thickness of the first silicon dioxide layer 2201 is, e.g., in a range from 100 nm to 1000 nm, advantageously in a range from 100 nm to 450 nm, such as, e.g., at 330 nm.

A first silicon nitride layer 2301 is deposited 130 on the first silicon dioxide layer 2201. The first silicon nitride layer 2301 is deposited, for example, by means of low-pressure vapor deposition, i.e. using an LPCVD method. The first silicon nitride layer 2301 comprises, e.g., Si3N4 material. A thickness of the first silicon nitride layer 2301 is, e.g., in a range from 100 nm to 1000 nm, advantageously in a range from 100 nm to 550 nm, such as, e.g., at 460 nm.

A second silicon dioxide layer 2202 is deposited 140 on the first silicon nitride layer 2301. Here, a polycrystalline silicon layer 222, i.e. polysilicon, is deposited 142 on the first silicon nitride layer 2301 and oxidized 144. The polycrystalline silicon layer 222 is, for example, undoped. The polycrystalline silicon layer 222 is deposited, e.g., by means of low-pressure vapor deposition, i.e. using an LPCVD method. The oxidation 144 of the polycrystalline silicon layer 222 is performed, for example, dry-chemically or wet-chemically, wherein dry-chemical oxidation is advantageous. A thickness of the second silicon dioxide layer 2202 is, e.g., in a range from 100 nm to 1000 nm, advantageously in a range from 100 nm to 450 nm, such as, e.g., at 330 nm.

The method 100 further comprises depositing 150 a second silicon nitride layer 2302 on the second silicon dioxide layer 2202. The second silicon nitride layer 2302 is deposited, for example, by means of low-pressure vapor deposition, i.e. using an LPCVD method. The second silicon nitride layer 2302 comprises, e.g., Si3N4 material. A thickness of the second silicon nitride layer 2302 is, e.g., in a range from 100 nm to 1000 nm, advantageously in a range from 100 nm to 550 nm, such as, e.g., at 530 nm.

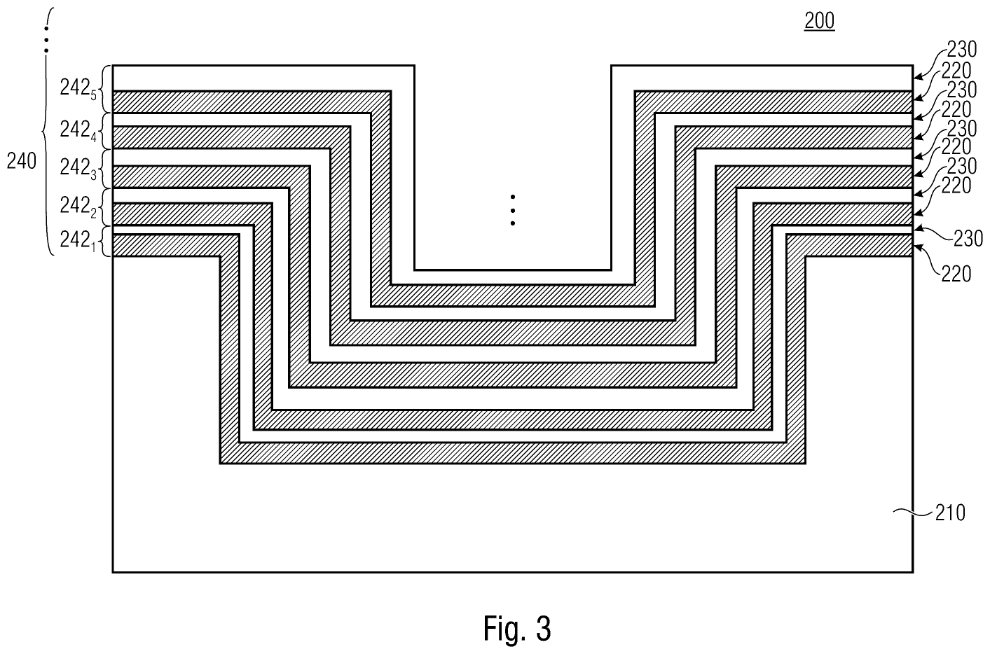

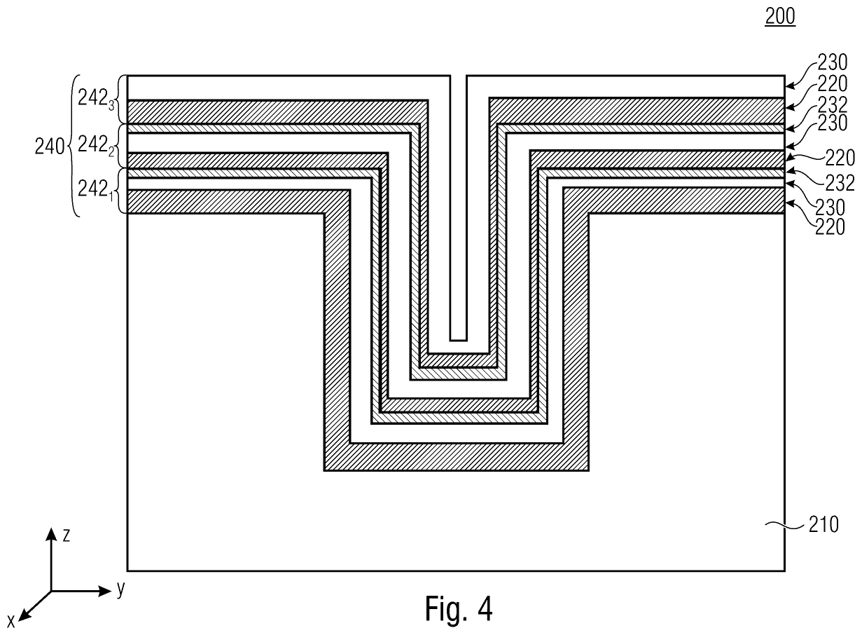

Thus, a trench capacitor, see the trench capacitor structure 200, is formed or provided with a dielectric layer structure 240. The dielectric layer structure 240 comprises the first silicon dioxide layer 2201, the first silicon nitride layer 2301, the second silicon dioxide layer 2202 and the second silicon nitride layer 2302. Optionally, the dielectric layer structure 240 can comprise further silicon dioxide and silicon nitride layers, see, e.g., FIGS. 3 and 4. The dielectric layer structure 240 is arranged at least in the plurality of recesses 212, e.g., on surfaces of the plurality of recesses 212. Optionally, the dielectric layer structure 240 is further arranged on the main surface 214 of the silicon substrate 210 or on parts of the main surface 214 of the silicon substrate 210.

The first silicon dioxide layer 2201, the first silicon nitride layer 2301, the second silicon dioxide layer 2202 and the second silicon nitride layer 2302 are arranged, e.g., adjacent to one another in this order. The dielectric layer structure 240 can also be considered as a layer stack having dielectric layers, see the layers 2201, 2202, 2301 and 2302. The first silicon dioxide layer 2201 is, for example, arranged directly on the substrate 210 of the trench capacitor and the first silicon nitride layer 2301, the second silicon dioxide layer 2202 and the second silicon nitride layer 2302 are arranged, e.g., in this order on the first silicon dioxide layer 2201. The order of the dielectric layers of the dielectric layer structure 240 is indicated, for example, from the silicon substrate 210 in the layer stacking direction.

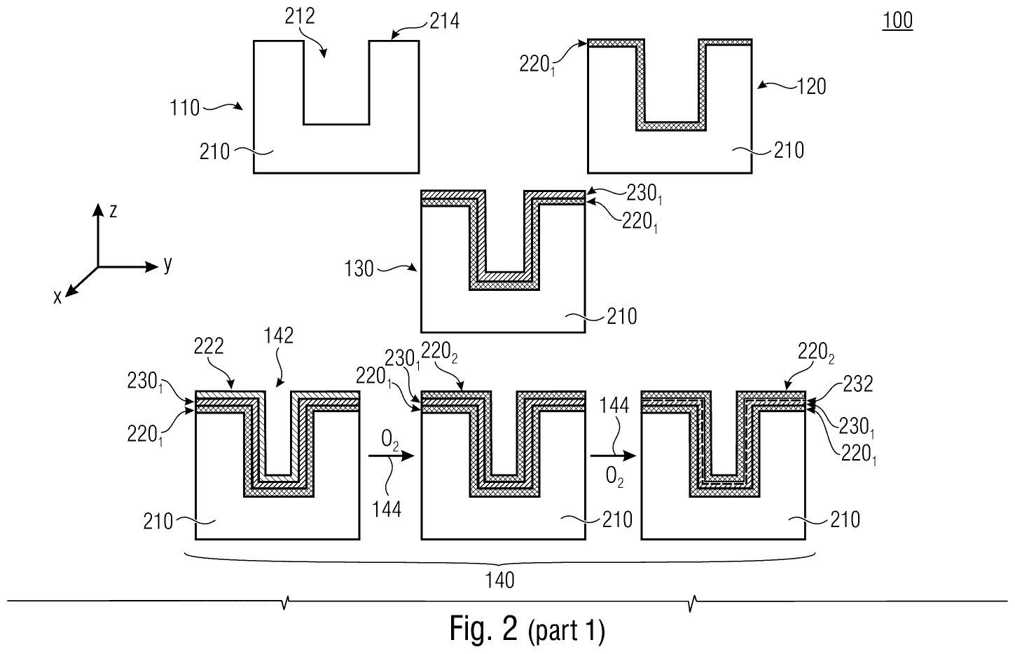

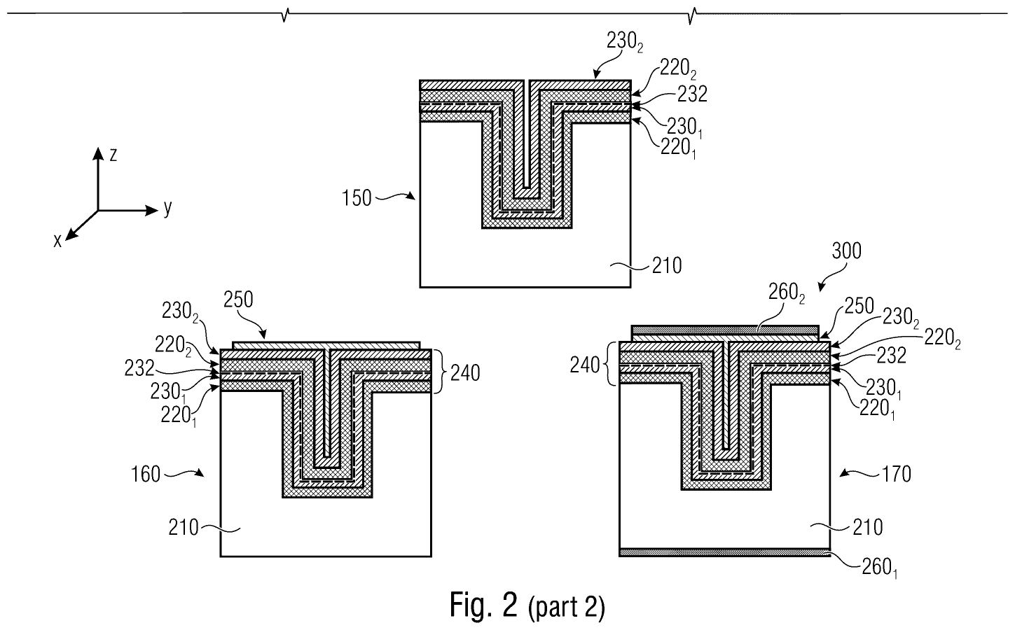

Optionally, the method 100 can comprise further steps as described in connection with FIG. 2. Likewise, the trench capacitor structure 200 can comprise, e.g., further layers as described in connection with FIG. 2. The first silicon nitride layer 2301 can comprise, e.g., the oxynitride layer 232 described in the context of FIG. 2. The oxynitride layer 232 of the first silicon nitride layer 2301 is arranged, e.g., at an interface between the first silicon nitride layer 2301 and the second silicon dioxide layer 2202.

FIG. 2 shows exemplarily the method 100 for a section of a trench capacitor structure 200 formed by the method. In other words, a recess 212 of the plurality of recesses of the trench structure in the silicon substrate 210 and the layers deposited therein are schematically shown in detail. That is, FIG. 2 shows the method steps in detail for one of the plurality of recesses of the trench structure. Even if FIG. 2 shows the method steps only in connection with a recess 212 of the plurality of recesses, it is obvious that the method steps can also be applied in connection with the remaining recesses of the plurality of recesses.

The method 100 in FIG. 2 comprises, like the method 100 in FIGS. 1a and 1b, the steps of providing 110 the silicon substrate 210; forming 120 the first silicon dioxide layer 2201 in the recesses 212 of the silicon substrate 210; depositing 130 the first silicon nitride layer 2301 on the first silicon dioxide layer 2201; depositing 140 the second silicon dioxide layer 2202 on the first silicon nitride layer 2301; and depositing 150 the second silicon nitride layer 2302 on the second silicon dioxide layer 2202.

As described in connection with FIGS. 1a and 1b, depositing 140 the second silicon dioxide layer 2202 on the first silicon nitride layer 2301 comprises depositing 142 the polycrystalline silicon layer 222 and oxidizing 144 the polycrystalline silicon layer 222. The oxidizing 144 can be performed, e.g., dry-chemically or wet-chemically. During oxidizing 144 the polycrystalline silicon layer 222, an oxynitride layer 232 is optionally formed between the first silicon nitride layer 2301 and the second silicon dioxide layer 2202, or in the first silicon nitride layer 2301 at an interface between the first silicon nitride layer 2301 and the second silicon dioxide layer 2202. The polycrystalline silicon layer 222 is, e.g., completely converted into the second silicon dioxide layer 2202, i.e., completely oxidized, and optionally, subsequent thereto, oxidizing 144 is continued in order to partially oxidize the first silicon nitride layer 2301 and to form the oxynitride layer 232 in the first silicon nitride layer 2301, or at an interface between the first silicon nitride layer 2301 and the second silicon dioxide layer 2202. The nitride surface of the first silicon nitride layer 2301 is, e.g., oxidized to a depth of a few nm by continuing the oxidizing 144 for longer than is needed for the complete consumption of the polycrystalline silicon. This step is optional and is intended, in particular, to optimize the interface between oxide and nitride/to make the same more defect-free. The first silicon nitride layer 2301 serves, e.g., as an oxidation stop. An oxidation period of the oxidizing 144 is, e.g., in a range of 5 h-72 h, 5 h-48 h or 5 h-32 h, such as, e.g., 9.75 h or 10 h. The oxidizing 144 is performed, e.g., depending on a thickness. of the second silicon dioxide layer 2202 to be formed, for a period of at least 5 h, 9 h or 24 h in order to ensure that the polycrystalline silicon layer 222 has been completely converted into the second silicon dioxide layer 2202 and the oxynitride layer 232 has been formed. The thicker the second silicon dioxide layer 2202 to be formed or the polycrystalline silicon layer 222 to be oxidized, the longer the oxidation 144 should be performed.

The oxynitride layer 232 comprises, e.g., thermal oxide. A thickness of the oxynitride layer 232 is, e.g., in a range from 1 nm to 12 nm or 1 nm to 11 nm. The oxynitride layer 232 advantageously has a maximum thickness of 11 nm.

The first silicon dioxide layer 2201, the first silicon nitride layer 2301, the oxynitride layer 232, the second silicon dioxide layer 2202 and the second silicon nitride layer 2302 form, e.g., a dielectric layer structure 240.

Optionally, a layer 250 with doped polysilicon material can be deposited 160 on the second silicon nitride layer 2302. The layer 250 with doped polysilicon material is, for example, deposited 160 such that at least the recesses 212 in which the silicon dioxide and silicon nitride layers are arranged are filled with the doped polysilicon material. The layer 250 with doped polysilicon material completes, for example, the plurality of recesses 212. The layer 250 with doped polysilicon material can further be deposited 160 on a surface of the second silicon nitride layer 2302 facing away from the main surface of the silicon substrate 210. The layer 250 with doped polysilicon material is, for example, deposited 160 such that a surface parallel to the main surface 214 of the silicon substrate 210 is formed on a side of the layer 250 facing away from the dielectric layer structure 240. The layer 250 with doped polysilicon material is deposited, e.g., by means of low-pressure vapor deposition, i.e. using an LPCVD method. The doped polysilicon material is, for example, in situ doped polycrystalline silicon material. The layer 250 with doped polysilicon material forms, e.g., an electrode, such as, e.g., a front electrode, of an RC snubber element 300.

Optionally, further, an aluminum layer, see 2601 and 2602, can be respectively deposited 170 on the layer 250 with doped polysilicon material and on a side of the silicon substrate 210 facing away from the dielectric layer structure 240. The aluminum layers 2601 and 2602 are, for example, front and back metallizations of an RC snubber element 300.

A trench capacitor or an RC snubber element 300 comprises, e.g., a silicon substrate 210 with a trench structure comprising a plurality of recesses 212 and the dielectric layer structure 240 at least in the recesses 212 of the silicon substrate 210. The first silicon dioxide layer 2201 of the dielectric layer structure 240 is, for example, arranged directly on the substrate 210 of the trench capacitor and the first silicon nitride layer 2301 with the oxynitride layer 232, the second silicon dioxide layer 2202 and the second silicon nitride layer 2302 are arranged, e.g., in this order on the first silicon dioxide layer 2201. The order of the dielectric layers of the dielectric layer structure 240 is indicated, for example, from the silicon substrate 210 in the layer stacking direction. Optionally, the trench capacitor comprises a doped polycrystalline silicon layer, see the layer 250, on a surface of the dielectric layer structure 240 facing away from the silicon substrate 210. Further, the trench capacitor can comprise, e.g., a first aluminum layer 2601 on a surface of the silicon substrate 210 opposite the main surface 214 and can comprise a second aluminum layer 2602 on a surface of the doped polycrystalline silicon layer facing away from the main surface 214.

FIGS. 1a-2 show (ON)x snubber processing with x=2. However, methods 100 or a trench capacitor structure 200, e.g., for a trench capacitor or for an RC snubber element 300, having more ON layer pairs, i.e., silicon dioxide-silicon nitride layer pairs, are also possible. FIG. 3 shows exemplarily a trench capacitor structure 200 with x≥5 and FIG. 4 shows exemplarily a trench capacitor structure 200 with x=3. The silicon dioxide layers discussed herein can also be referred to as oxide layers or with the letter O. The silicon nitride layers discussed herein can also be referred to as nitride layers or with the letter N.

As illustrated in FIGS. 3 and 4, a dielectric layer structure 240 described herein can comprise three or more silicon dioxide-silicon nitride layer pairs, i.e., ON layer pairs 242, see, e.g., 2421-5 in FIGS. 3 and 2421-3 in FIG. 4. A silicon dioxide layer 220 and a silicon nitride layer 230 together form an ON layer pair 242. Viewed from the silicon substrate 210 in the layer stacking direction, i.e. in the direction of the dielectric layer structure 240, e.g., within an ON layer pair 242, the respective silicon nitride layer 230 is arranged on the respective silicon dioxide layer 220.

The ON layer pairs 242 are disposed one above the other in the layer stacking direction. Starting from the second layer pair 2422, the respective silicon dioxide layer 220 is arranged on a silicon nitride layer 230 of the respectively preceding layer pair 242. The dielectric layer structure 240 comprises, e.g., a layer stack with alternating silicon dioxide and silicon nitride layers.

Starting from the second layer pair 2422, the respective silicon dioxide layer 220 is deposited by depositing a polycrystalline silicon layer and oxidizing the polycrystalline silicon layer. Optionally, after the respective polycrystalline silicon layer has been completely converted into the respective silicon dioxide layer 220, oxidizing can be continued in order to oxidize the nitride surface of the respective silicon nitride layer 2301 on which the respective silicon dioxide layer 220 is arranged and to form a respective oxynitride layer 232.

In a dielectric layer structure 240 with x ON layer pairs 242, as exemplarily shown in FIG. 4, the first silicon nitride layer 230 up to the (x−1) th silicon nitride layer 230 can each comprise an oxynitride layer 232, wherein x≥3. The oxynitride layers are respectively arranged, e.g., at an interface to a subsequent layer pair 242. That is, when a new layer pair 242 is formed on a preceding layer pair 242, a nitride surface of the silicon nitride layer 230 of the preceding layer pair is, e.g., oxidized to a depth of a few nm in order to form the oxynitride layer 232, wherein the nitride surface is arranged facing the new layer pair 242.

According to an embodiment, the oxynitride layers 232 can alternatively be considered as independent layers, which are each arranged between two consecutive ON layer pairs 242.

Optionally, the trench capacitor structures 200 illustrated in FIGS. 3 and 4 can further comprise the doped polycrystalline silicon layer 250 described in connection with FIG. 2 and/or the aluminum layers 1601 and 2602.

Instead of, as in the patent DE102019204503B3 mentioned at the beginning of this application, relying on stress-free nitride, silicon dioxide (thermally grown) and silicon nitride (deposited via LPCVD), see patent DE102014223904A1, are again generated on the underlying dielectric layers (silicon dioxide under silicon nitride) in any number, greater than two, of repetitions with layer thicknesses of 100 nm to 1000 nm each and thus the opposite material voltages continue to be used to reduce or control the wafer bending and the breakdown voltage is significantly increased in the process. Due to the mechanical voltages acting against each other, the hole depth and thus the surface enlargement of the capacitor can be increased and the integration density can be obtained or even increased even with a thicker overall dielectric stack layer.

In order to maximize the quality of the silicon dioxide layers 220, the same are generated by means of thermal oxidation. The first silicon dioxide layer 2201 is thus thermally grown on the silicon substrate 210, for the further silicon dioxide layers 2202-220x (with x≥3), a respective layer of undoped polycrystalline silicon (100-1000 nm) is deposited on the respective silicon nitride layers 2301-230x-1 (with x≥3) by means of LPCVD and thermally completely dry-chemically oxidized or reoxidized. After the respective polycrystalline silicon layer 222 has been completely converted into silicon dioxide 220, it is further oxidized for a certain time so that the silicon nitride 230 is also somewhat oxidized and an oxynitride layer 232 is formed. This results in a clean interface between the silicon nitride layer 230 and the silicon dioxide layer 220, the silicon nitride serves here quasi as a “growth stop” and is only slightly oxidized due to the very low dry oxidation rate of silicon nitride per se (see R. L. Guldi et al. 1989 J. Electrochem. Soc. 136 3815, DOI 10.1149/1.2096555) and the partially thick silicon dioxide layer 220 (formerly polycrystalline silicon 222) above the same, which slows down the diffusion of the oxygen to the silicon nitride. Due to a constant compensation of the mechanical voltages due to the opposite pressures of silicon nitride and silicon oxide, the wafer bending is kept as low as possible, whereby the integration density can be further increased by increasing the hole depth and at the same time the thickness of the entire dielectric stack, and thus the breakdown strength.

An increase of the breakdown strength could be achieved with the previously known materials and methods only via an increase of the total layer thickness. This results, on the one hand, in an increase of the wafer bending and, on the other hand, in a reduction of the integration density. If one wishes to increase the integration density, deeper holes have to be produced, which in turn increases the wafer bending. As a solution, the mutual mechanical pressures of the dielectrics used herein, i.e. the silicon dioxide layer 220 and silicon nitride layer 230, are used, namely by disposing at least two silicon dioxide layers 220 and at least two silicon nitride layers 230 alternately one above the other. In order to link this with the best possible electrical properties, instead of LPCVD or PECVD methods, dry-chemical oxidizing or oxidizing or up-oxidizing or reoxidizing of the polysilicon is used in order to form the silicon dioxide layer 220 and to generate the layer stack.

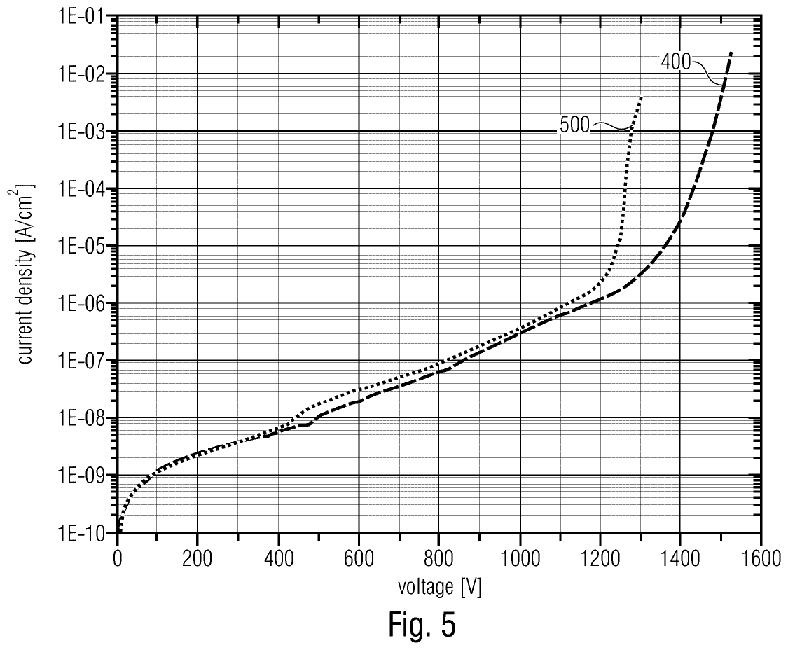

By means of deposition of the silicon dioxide layers directly on the silicon nitride layers, e.g., via LPCVD or PECVD methods, a basically similar stack can be generated. However, the interfaces have more defects when using LPCVD or PECVD methods and the electrical breakdown strength is significantly lower, see FIG. 5. FIG. 5 shows a first characteristic curve 400 for a device which has been produced according to FIG. 2 and has an equivalent oxide thickness of approximately 1175 nm. The silicon dioxide layers of the device on which the characteristic curve 400 is based have been deposited by means of dry-chemical oxidation. Further, FIG. 5 shows a second characteristic curve 500 for an identically constructed device, in which, however, the silicon dioxide layers have been deposited by means of LPCVD deposition and not by means of dry-chemical oxidation of a polysilicon layer.

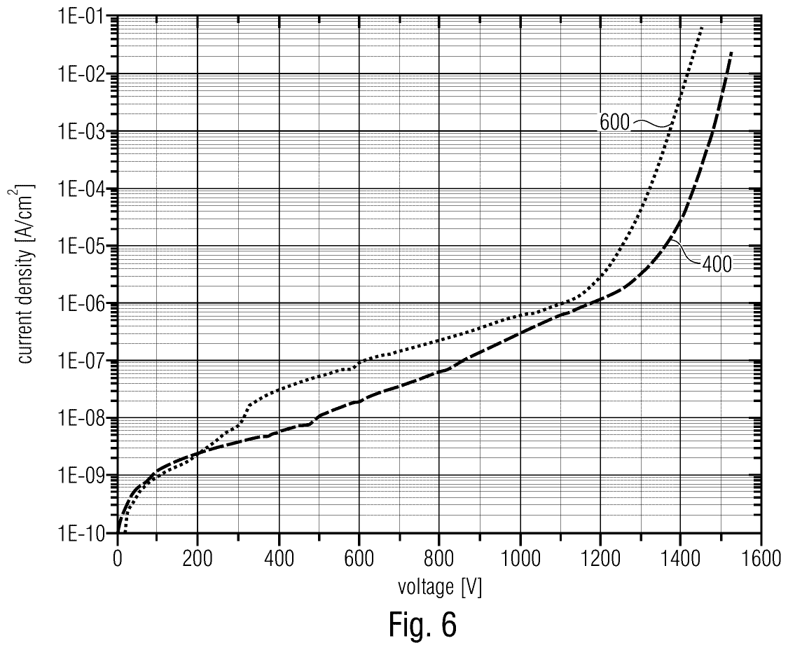

Also, the polycrystalline silicon can be wet-chemically reoxidized instead of dry-chemically, which also functions more quickly in terms of process technology, but also has a lower breakdown strength, see FIG. 6. FIG. 6 shows a first characteristic curve 400 for a device which has been produced according to FIG. 2 and has an equivalent oxide thickness of approximately 1175 nm. The silicon dioxide layers of the device on which the characteristic curve 400 is based have been deposited by means of dry-chemical oxidation.

Further, FIG. 6 shows a second characteristic curve 600 for a device also produced according to FIG. 2, in which, however, silicon dioxide layers (e.g., at least the silicon dioxide layers starting from the second silicon dioxide layer 2202) have been deposited by means of moist-chemical or wet-chemical oxidation of a polysilicon layer and not by means of dry-chemical oxidation of a polysilicon layer.

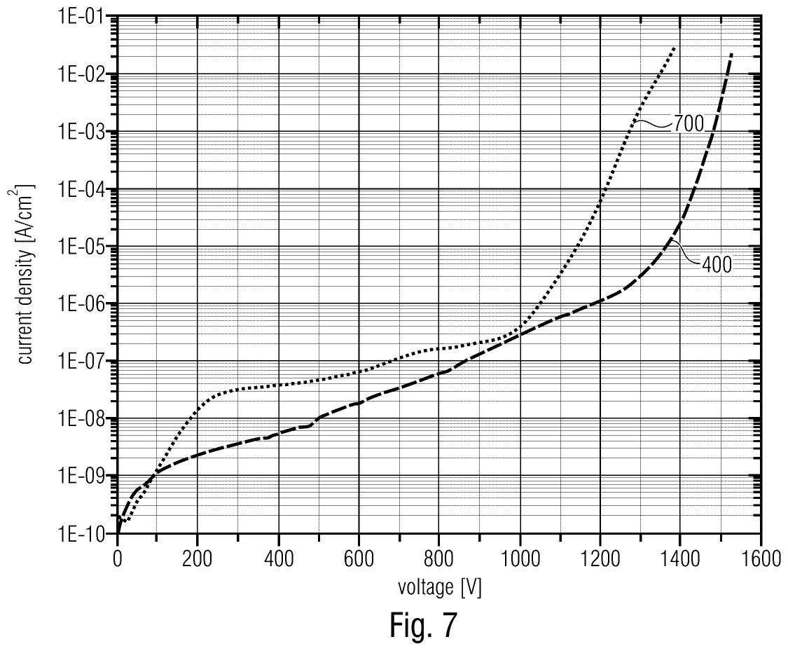

Further, the device according to FIG. 2 also has a higher breakdown strength compared to devices with stress-free nitride layer, as known from DE102019204503B3. FIG. 7 shows a first characteristic curve 400 for a device which has been produced according to FIG. 2 and has an equivalent oxide thickness of approximately 1175 nm. The silicon dioxide layers of the device on which the characteristic curve 400 is based have been deposited by means of dry-chemical oxidation. Further, FIG. 7 shows a second characteristic curve 700 for a device with a dielectric layer structure with 330 nm SiO2, 550 nm Si3N4, 500 nm SixNy and 500 nm Si3N4 with an equivalent oxide thickness of approximately 1085 nm.

With the methods 100 described herein, devices, e.g., RC snubber elements, with voltage classes of at least 1000 V, 1200 V or even of at least 1500 V can be provided. For example, a device according to FIG. 2 with an oxide thickness of a total of 680 nm and a nitride thickness of a total of 1000 nm can achieve a breakdown voltage of 1500 V at 10 mA.

Whether a Si-RC snubber device has been produced with one of the methods 100 described herein can be found out by an FIB cross-sectional analysis (Focused Ion Beam with SEM imaging). The leakage current behavior at nominal voltage can indicate the quality of the used oxide, i.e. of the silicon dioxide layers 220, here, a rough distinction can be made between PECVD, wet-chemically grown and dry-chemically grown oxides (decreasing leakage current from PECVD to wet to dry oxide). Further, TEM analyses can be used for examining the used oxide layer generation (deposition vs. growth). A further possibility is to examine etching rate differences of the generated oxide layers.

With the methods described herein, snubber devices for overvoltage attenuation can be produced in power modules. With the snubber devices, for example, silicon carbide transistors in conventional power modules can be switched more quickly without module-induced induction leading to high voltage peaks, which could potentially be harmful to all devices in the module. Here, the capacitor absorbs the energy (in several cycles) and via the integrated resistor, this energy is converted into heat and dissipated. Possible fields of application of such modules are, for example, vehicle electronics (in the charging module or powertrain of e-mobility) or renewable energies (wind turbines, or the like). Due to the possibility of faster switching, the overall efficiency of the power modules can be increased, since less power loss occurs.

Although some aspects have been described in connection with an apparatus, it is understood that these aspects also represent a description of the corresponding method, so that a block or a device of an apparatus is also to be understood as a corresponding method step or as a feature of a method step. Analogously, aspects that have been described in connection with or as a method step also represent a description of a corresponding block or detail or feature of a corresponding apparatus. Some or all of the method steps can be carried out by a hardware apparatus (or using a hardware apparatus), such as, for example, a microprocessor, a programmable computer or an electronic circuit. In some embodiments, some or more of the most important method steps can be carried out by such an apparatus.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. Method for producing a trench capacitor structure, comprising:
providing a silicon substrate with a trench structure comprising a plurality of recesses in a main surface of the silicon substrate;
forming a first silicon dioxide layer at least in the recesses of the silicon substrate;
depositing a first silicon nitride layer on the first silicon dioxide layer;
depositing a second silicon dioxide layer on the first silicon nitride layer by depositing a polycrystalline silicon layer and oxidizing the polycrystalline silicon layer; and
depositing a second silicon nitride layer on the second silicon dioxide layer.

2. Method according to claim 1, wherein, during oxidizing the polycrystalline silicon layer, an oxynitride layer is formed between the first silicon nitride layer and the second silicon dioxide layer.

3. Method according to claim 1, wherein, during oxidizing the polycrystalline silicon layer, the polycrystalline silicon layer is completely converted into the second silicon dioxide layer.

4. Method according to claim 3, wherein after the polycrystalline silicon layer has been completely converted into the second silicon dioxide layer, oxidizing is continued in order to partially oxidize the first silicon nitride layer and to form an oxynitride layer between the first silicon nitride layer and the second silicon dioxide layer.

5. Method according to claim 1, wherein the polycrystalline silicon layer is undoped.

6. Method according to claim 1, wherein the polycrystalline silicon layer is deposited on the first silicon nitride layer by means of low-pressure vapor deposition.

7. Method according to claim 1, wherein the first silicon dioxide layer, the first silicon nitride layer, the second silicon dioxide layer and the second silicon nitride layer are deposited with a respective layer thickness in a range from 100 nm to 1000 nm.

8. Method according to claim 1, wherein forming the first silicon dioxide layer at least in the recesses of the silicon substrate is performed by means of thermal growth;
depositing the first silicon nitride layer on the first silicon dioxide layer is performed by means of low-pressure vapor deposition; and
depositing the second silicon nitride layer on the second silicon dioxide layer is performed by means of low-pressure vapor deposition.

9. Method according to claim 1, wherein a silicon nitride layer on a silicon dioxide layer form a layer pair,
wherein the first silicon dioxide layer and the first silicon nitride layer form a first layer pair and the second silicon dioxide layer and the second silicon nitride layer form a second layer pair,
wherein at least one further layer pair is deposited on the second layer pair, and
wherein starting from the second layer pair, the respective silicon dioxide layer is deposited by depositing a polycrystalline silicon layer and oxidizing the polycrystalline silicon layer.

10. Method according to claim 9, wherein the at least one further layer pair is deposited on the second layer pair such that a layer structure with alternating silicon dioxide and silicon nitride layers is formed.

11. Method according to claim 1, wherein oxidizing the polycrystalline silicon layer is performed by means of dry-chemical oxidation or wet-chemical oxidation.

12. Method according to claim 1 for forming an RC snubber element.

13. Trench capacitor comprising:
a dielectric layer structure comprising a first silicon dioxide layer, a first silicon nitride layer, a second silicon dioxide layer and a second silicon nitride layer;
wherein the first silicon dioxide layer, the first silicon nitride layer, the second silicon dioxide layer and the second silicon nitride layer are adjacent to one another in this order.

14. Trench capacitor according to claim 13, wherein a layer thickness of the first silicon dioxide layer, the first silicon nitride layer, the second silicon dioxide layer and the second silicon nitride layer is in a range from 100 nm to 1000 nm.

15. Trench capacitor according to claim 13, wherein the trench capacitor is produced by means of the method for producing a trench capacitor structure, the method comprising:
providing a silicon substrate with a trench structure comprising a plurality of recesses in a main surface of the silicon substrate;
forming a first silicon dioxide layer at least in the recesses of the silicon substrate;
depositing a first silicon nitride layer on the first silicon dioxide layer;
depositing a second silicon dioxide layer on the first silicon nitride layer by depositing a polycrystalline silicon layer and oxidizing the polycrystalline silicon layer; and
depositing a second silicon nitride layer on the second silicon dioxide layer.
